(19) United States
(12) Patent Application Publication
(10) Pub. No.: US 2007/0123010 A1
(43) Pub. Date: May 31, 2007

(54) TECHNIQUE FOR REDUCING CRYSTAL DEFECTS IN STRAINED TRANSISTORS BY TILTED PREAMORPHIZATION

(76) Inventors: Jan Hoentschel, Neustadt (DE); Andy Wei, Dresden (DE); Mario Heinze, Laubusch (DE); Peter Javorka, Dresden (DE)

Correspondence Address: WILLIAMS, MORGAN & AMERSON, 10333 RICHMOND, SUITE 1100, HOUSTON, TX, 77042, US

(21) Appl. No.: 11/530,722

(22) Filed: Sep. 11, 2006

(30) Foreign Application Priority Data
Nov. 30, 2005 (DE) 10 2005 057 074.7

(51) Int. Cl. H01L 21/336; H01L 21/20

(52) U.S. Cl. 438/486; 438/302

(57) ABSTRACT

By performing a tilted amorphization implantation and a subsequent re-crystallization on the basis of a stressed overlying material, a highly efficient strain-inducing mechanism is provided. The tilted amorphization implantation may result in a significantly reduced defect rate during the re-crystallization process, thereby substantially reducing leakage currents in sophisticated transistor elements.

### BACKGROUND OF THE INVENTION

1. Field of the Invention

Generally, the present invention relates to the formation of integrated circuits, and, more particularly, to the formation of transistors having strained channel regions by using stress-inducing sources, such as embedded strain layers and the like, to enhance charge carrier mobility in the channel region of a MOS transistor.

2. Description of the Related Art

The fabrication of integrated circuits requires the formation of a large number of circuit elements on a given chip area according to a specified circuit layout. Generally, a plurality of process technologies are currently practiced, wherein, for complex circuitry, such as microprocessors, storage chips and the like, CMOS technology is currently one of the most promising approaches, due to the superior characteristics in view of operating speed and/or power consumption and/or cost efficiency. During the fabrication of complex integrated circuits using CMOS technology, millions of transistors, i.e., N-channel transistors and P-channel transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an inversely doped channel region disposed between the drain region and the source region.

The conductivity of the channel region, i.e., the drive current capability of the conductive channel, is controlled by a gate electrode formed close to the channel region and separated therefrom by a thin insulating layer. The conductivity of the channel region upon formation of a conductive channel, due to the application of an appropriate control voltage to the gate electrode, depends on the dopant concentration, the mobility of the majority charge carriers, and, for a given extension of the channel region in the transistor width direction, on the distance between the source and drain regions, which is also referred to as channel length. Hence, the conductivity of the channel region is a dominant factor determining the performance of MOS transistors. Thus, the reduction of the channel length, and associated therewith the reduction of the channel resistivity, renders the channel length an important design criterion for accomplishing an increase in the operating speed of the integrated circuits.

The continuing shrinkage of the transistor dimensions, however, involves a plurality of issues associated therewith that have to be addressed so as to not unduly offset the advantages obtained by steadily decreasing the channel length of MOS transistors. One major problem in this respect is the development of enhanced photolithography and etch strategies to reliably and reproducibly create circuit elements of critical dimensions, such as the gate electrode of the transistors, for a new device generation. Moreover, highly sophisticated dopant profiles, in the vertical direction as well as in the lateral direction, are required in the drain and source regions in order to provide low sheet and contact resistivity in combination with a desired channel controllability. In addition, the vertical location of the PN junctions with respect to the gate insulation layer also represents a critical design criterion in view of leakage current control, since reducing the channel length may usually also require reducing the depth of the drain and source regions with respect to the interface formed by the gate insulation layer and the channel region, thereby requiring sophisticated implantation tech- niques. According to other approaches, epitaxially grown regions are formed with a specified offset to the gate electrode, which are referred to as raised drain and source regions, to provide increased conductivity of the raised drain and source regions, while at the same time maintaining a shallow PN junction with respect to the gate insulation layer.

Since the continuous size reduction of the critical dimensions, i.e., the gate length of the transistors, necessitates the adaptation and possibly the new development of highly complex process techniques concerning the above-identified process steps, it has been proposed to also enhance the channel conductivity of the transistor elements by increasing the charge carrier mobility in the channel region for a given channel length, thereby offering the potential for achieving a performance improvement that is comparable with the advance to a future technology node, while avoiding or at least postponing many of the above process adaptations associated with device scaling. One efficient mechanism for increasing the charge carrier mobility is the modification of the lattice structure in the channel region, for instance by creating tensile or compressive stress in the vicinity of the channel region so as to produce a corresponding strain in the channel region, which results in a modified mobility for electrons and holes, respectively. For example, creating tensile strain in the channel region increases the mobility of electrons, wherein, depending on the magnitude and direction of the tensile strain, an increase in mobility of 50% or more may be obtained, which, in turn, may directly translate into a corresponding increase in the conductivity. On the other hand, compressive strain in the channel region may increase the mobility of holes, thereby providing the potential for enhancing the performance of P-type transistors. The introduction of stress or strain engineering into integrated circuit fabrication is an extremely promising approach for further device generations, since, for example, strained silicon may be considered as a “new” type of semiconductor material, which may enable the fabrication of fast powerful semiconductor devices without requiring expensive semiconductor materials, while many of the well-established manufacturing techniques may still be used.

Consequently, it has been proposed to introduce, for instance, a silicon/germanium layer or a silicon/carbon layer in or below the channel region to create tensile or compressive stress that may result in a corresponding strain. Although the transistor performance may be considerably enhanced by the introduction of stress-creating layers in or below the channel region, significant efforts have to be made to implement the formation of corresponding stress layers into the conventional and well-approved MOS technique. For instance, additional epitaxial growth techniques have to be developed and implemented into the process flow for forming the germanium or carbon-containing stress layers at appropriate locations in or below the channel region. Hence, process complexity is significantly increased, thereby also increasing production costs and the potential for a reduction in production yield.

Thus, in other approaches, external stress created by, for instance, overlaying layers, spacer elements and the like are used in an attempt to create a desired strain within the channel region. Although a promising approach, the process of creating the strain in the channel region by applying a specified external stress may depend on the efficiency of the stress transfer mechanism for the external stress provided, for instance, by contact layers, spacers and the like into the channel region to create the desired strain therein. Hence, although providing significant advantages in terms of process complexity over the above-discussed approach requiring additional stress layers within the channel region, the efficiency of the stress transfer mechanism may depend on the process and device specifics and may result in a reduced performance gain for one type of transistor.

In another approach, the hole mobility of PMOS transistors is enhanced by forming a strained silicon/germanium layer in the drain and source regions of the transistors, wherein the compressively strained drain and source regions create uniaxial strain in the adjacent silicon channel region. To this end, the drain and source regions of the PMOS transistors are selectively recessed, while the NMOS transistors are masked, and subsequently the silicon/germanium layer is selectively formed in the PMOS transistor by epitaxial growth. Although this technique offers significant advantages in view of performance gain of the PMOS transistor and thus of the entire CMOS device, an appropriate design may have to be used that balances the difference in performance gain of the PMOS transistor and the NMOS transistor.

In still a further approach, a substantially amorphized region is formed adjacent to the gate electrode by ion implantation and the amorphized region is then re-crystallized in the presence of a stress layer formed above the transistor area, as will be described in more detail with reference to FIGS. 1a-1c.

FIG. 1a schematically shows a semiconductor device 100 comprising a substrate 101, such as a silicon substrate having formed thereon a buried insulating layer 102, above which is formed a crystalline silicon layer 103. Moreover, the semiconductor device 100 comprises a gate electrode 104 formed above the silicon layer 103 and separated therefrom by a gate insulation layer 105. Moreover, a liner 106, for instance comprised of silicon dioxide, is conformally formed on the gate electrode 104 and the silicon layer 103. The semiconductor device 100 is exposed to an ion implantation process 108 which may be designed such that a region 112 of the silicon layer 103 located adjacent to the gate electrode 104 is substantially amorphized. Furthermore, a doped region 107 may be formed within the layer 103 and may comprise any appropriate doping species that is required for the specific transistor to be formed by means of the gate electrode 104.

A typical process flow for forming the semiconductor device 100 may comprise the following processes. After forming or providing the substrate 101 having formed thereon the buried insulating layer 102 and the silicon layer 103, appropriate implantation sequences may be performed to establish a desired vertical dopant profile within the layer 103, which, for convenience, is not shown in FIG. 1a. Thereafter, any appropriate isolation structures (not shown), such as shallow trench isolations or the like, may be formed. Next, an appropriate dielectric material may be formed by deposition and/or oxidation, followed by the deposition of an appropriate gate electrode material, wherein both layers may then be patterned on the basis of sophisticated photolithography and etch techniques. Subsequently, the liner 106 may be formed on the basis of well-established plasma enhanced chemical vapor deposition (PECVD) techniques, wherein, depending on the process requirements and strategy, the liner 106 may act as an offset spacer for the formation of the doped region 107 on the basis of well-established implantation techniques. Furthermore, prior to or after the formation of the doped region 107, which may comprise a P-type dopant or an N-type dopant, depending on whether a P-channel transistor or an N-channel transistor is to be formed, an amorphization implantation process 108 may be performed. For this purpose, an appropriate dose and energy for an implant species under consideration may be selected on the basis of well-established recipes, thereby forming the substantially amorphized regions 112. For example, xenon, germanium and other heavy ions are suitable candidates for the amorphization implantation 108. Thereafter, a spacer layer may be formed above the semiconductor device 100 in such a way that the corresponding spacer layer may exhibit a specified type of intrinsic stress, such as tensile or compressive stress, wherein, after the deposition of the layer or after a subsequent patterning of the spacer layer into respective sidewall spacers on the basis of anisotropic etch techniques, an anneal process may be performed in order to re-crystallize the substantially amorphized regions 112.

FIG. 1b schematically shows the semiconductor device 100 after the completion of the above-described process sequence, in which a sidewall spacer 109 having a high intrinsic stress, in the present example indicated as a tensile stress, is formed on sidewalls of the gate electrode 104, while the substantially amorphized regions 112 are substantially re-crystallized and are now indicated as 112A. Due to the presence of the highly stressed spacer layer or the spacer 109, the re-crystallized regions 112A are re-grown in a strained state, thereby also creating a respective strain 110 in a channel region 115 located below the gate electrode 104. Thereafter, the semiconductor device 100 may be subjected to further manufacturing processes for providing a transistor element having the strained channel region 115.

FIG. 1c schematically shows the semiconductor device 100 with an additional spacer element 111 formed adjacent to the spacer 109 and with respective drain and source regions 113 formed within the silicon layer 103 and also partially within the strained re-crystallized region 112A. The device 100 may be formed in accordance with well-established processes, such as further implantation sequences, on the basis of the spacer element 111, in order to obtain the required dopant profile for the drain and source regions 113.

Consequently, an efficient technique for the creation of the strain 110 within the channel region 115 is provided which may lead to a significant enhancement in the charge carrier mobility and, thus, in the conductivity of the device 100. During the operation of the device 100, however, a significant increase in leakage current may be observed, which is believed to be caused by crystalline defects 114, which may also be referred to as “zipper defects,” and which may represent a source of reducing the minority charge carrier lifetime, thereby possibly significantly contributing to an increase of leakage current.

Although the approach described with respect to FIGS. 1a-1c provides the potential of a significant performance gain for N-channel transistors and P-channel transistors, the increased leakage current may render the conventional technique less attractive for the formation of sophisticated transistor devices.

In view of the situation described above, a need exists for an improved technique for the formation of transistor elements with a strained channel region while avoiding, or at least reducing, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to a technique in which at least one strain- inducing source is provided by re-crystallizing substantially amorphized regions on the basis of an overlying stressed layer or layer portion, wherein the substantially amorphized region may, however, substantially extend into the channel region and may therefore also be formed below a respective gate electrode. During a subsequent heat treatment, the creation of any crystalline defects may be significantly reduced compared to conventional techniques, thereby enhancing the performance of the respective transistor element in view of leakage currents.

According to one illustrative embodiment of the present invention, a method comprises forming a substantially amorphized region in an initially crystalline semiconductor layer adjacent to and extending below a gate electrode formed above the semiconductor layer, wherein the substantially amorphized region is formed by a tilted implantation process. Furthermore, the method comprises forming a stress layer having a specified intrinsic stress at least above a portion of the semiconductor layer to transfer stress into the semiconductor layer. Finally, the substantially amorphized region is re-crystallized in the presence of the stress layer by a heat treatment.

According to another illustrative embodiment of the present invention, a method comprises forming a first substantially amorphized region adjacent to and extending below a first gate electrode that is formed above an initially substantially crystalline semiconductor layer. Furthermore, a second substantially amorphized region is formed adjacent to and extending below a second gate electrode formed above the semiconductor layer. The method further comprises forming a first spacer at a sidewall of the first gate electrode, wherein the first spacer has a first type of stress. Moreover, a second spacer is formed at a sidewall of the second gate electrode, wherein the second spacer has a second type of stress that differs from the first type. Finally, the first and second substantially amorphized regions are re-crystallized in the presence of the first and second stressed spacers by means of a heat treatment.

### BRIEF DESCRIPTION OF THE DRAWINGS

The invention may be understood by reference to the following description taken in conjunction with the accompanying drawings, in which like reference numerals identify like elements, and in which:

FIGS. 1a-1c schematically show cross-sectional views of a transistor device formed according to a conventional process technique for re-crystallizing an amorphous semiconductor region in the presence of a stressed overlying material;

FIGS. 2a-2g schematically show cross-sectional views of a transistor element during various manufacturing stages, wherein a substantially amorphized region is formed adjacent to a gate electrode that significantly extends below the gate electrode in accordance with illustrative embodiments of the present invention; and

FIGS. 3a-3e schematically illustrate cross-sectional views of a semiconductor device including two different types of transistor elements, in which the re-crystallization of respective amorphized regions is performed on the basis of differently stressed spacer elements in accordance with illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present invention relates to a technique for the manufacture of transistor elements having a strained channel region, wherein at least one strain-inducing mechanism may be obtained by providing substantially amorphized regions adjacent to the gate electrodes and extending below the gate electrodes, i.e., extending into the channel region, and re-crystallizing these regions in the presence of a stressed overlying layer, such as a spacer layer or a spacer formed thereof. The present invention may be efficiently combined with other stress- and strain-inducing mechanisms, such as the provision of stressed contact layers that may be formed above the completed transistor elements and/or in combination with strained semiconductor layers, such as silicon/germanium layers, silicon/carbon layers and the like, which may be provided within respective drain and source regions of PMOS transistors and NMOS transistors, respectively. It should be understood that the term “NMOS” is to be considered as a generic notion for any type of N-channel field effect transistor and, similarly, the term “PMOS” is to be considered as a generic notion for any type of P-channel field effect transistor.

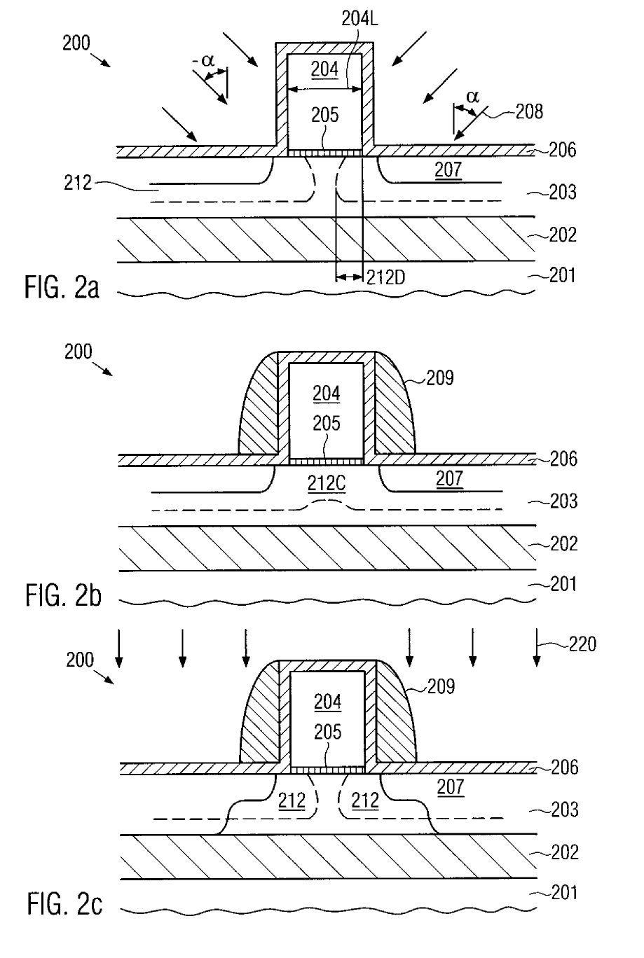

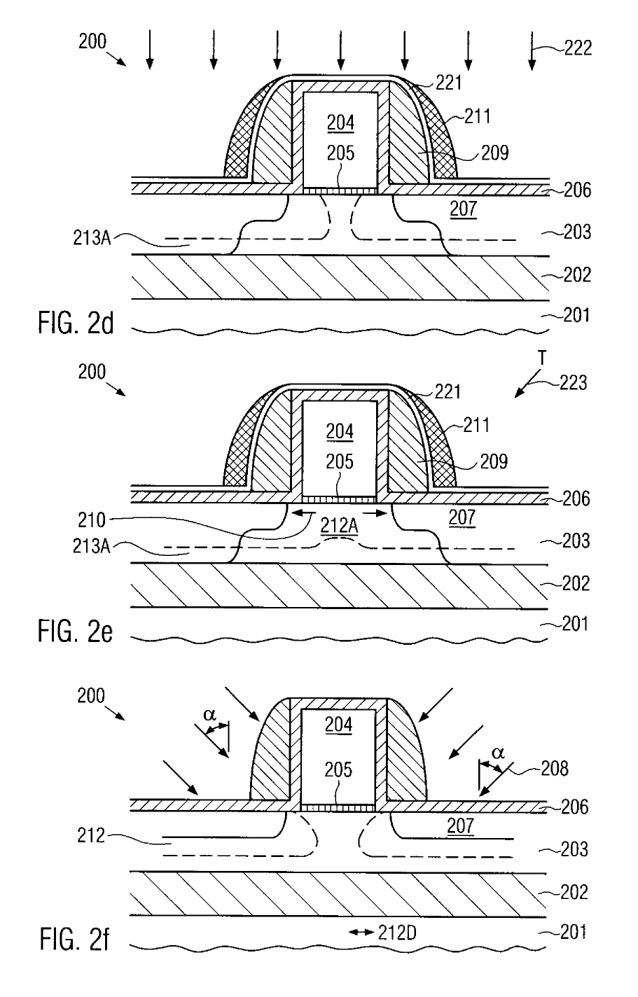

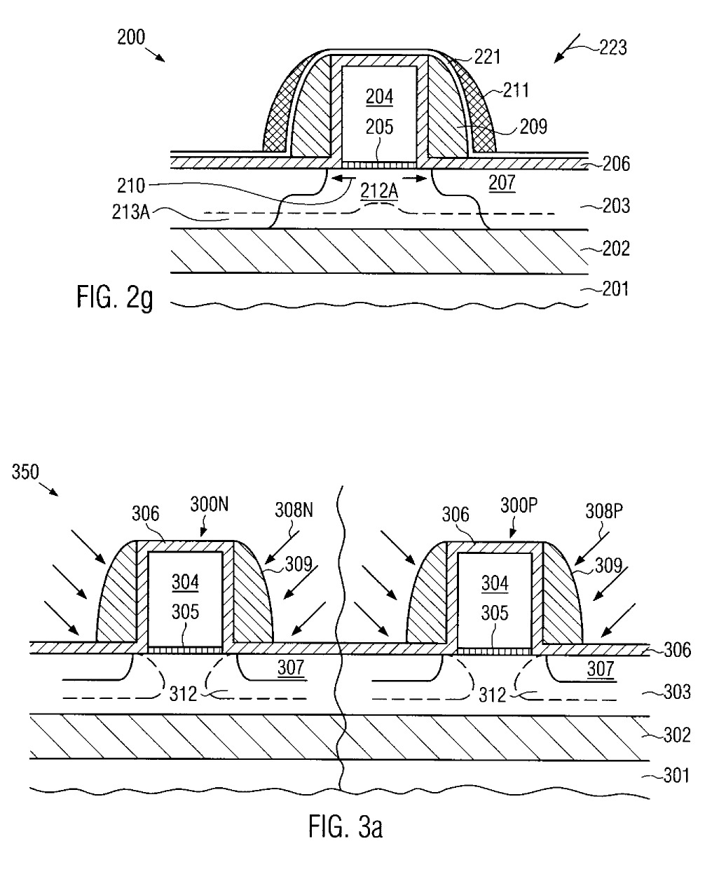

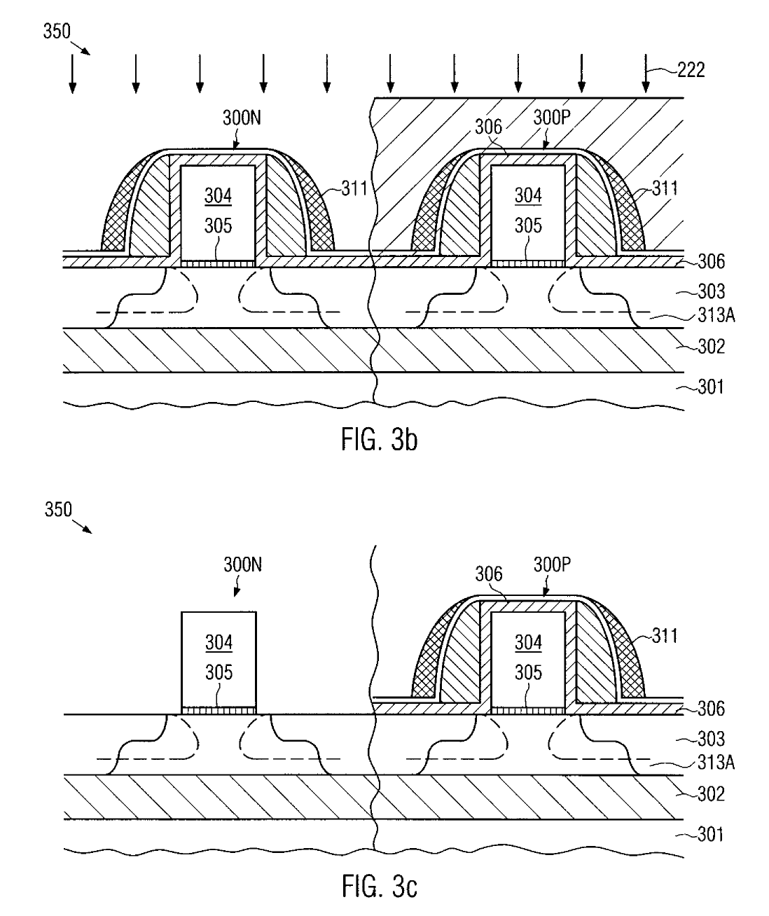

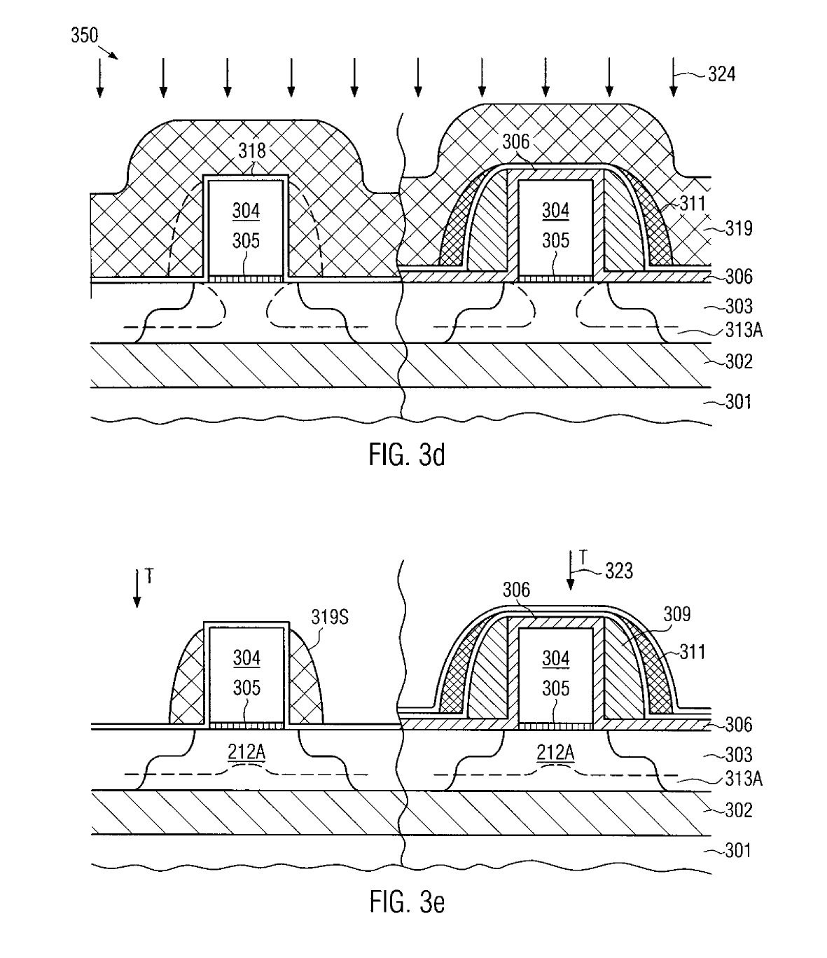

With reference to FIGS. 2a-2g and 3a-3e, further illustrative embodiments of the present invention will now be described in more detail. FIG. 2a schematically illustrates a cross-sectional view of a semiconductor device 200, which may represent a field effect transistor element, such as an N-channel transistor or a P-channel transistor. The semiconductor device 200 comprises a substrate 201, which may represent a bulk silicon substrate, a silicon-on-insulator (SOI) substrate, or any other appropriate carrier for forming thereon a substantially crystalline semiconductor layer for the formation of circuit elements, such as field effect transistors.

It should be appreciated that the present invention is highly advantageous in the context of silicon-based transistor elements, since here a significant increase in carrier mobility may be gained by providing a specific strain in certain regions of the transistor, such as the channel region, as is explained above. The principles of the present invention, however, may be readily applied to any type of semiconductor material, as long as a corresponding modification of the crystalline structure by strain may result in a corresponding performance gain. It should particularly be appreciated that a silicon-based semiconductor material is to be understood in the context of the present invention as any material that comprises a significant amount of silicon, which may be combined with any other appropriate semiconductor material. For example, a silicon-based semiconductor may be considered as a semiconductor material in which at least, in specific portions thereof, a high amount of silicon, that is, more than approximately 50 atomic percent, is provided, irrespective of whether other semiconductor materials in a more or less concentrated form may additionally be provided. For instance, a silicon/germanium semiconductor material having a germanium content of up to 30 atomic percent or even more may be considered as a silicon-based semiconductor material. Moreover, within a substantially crystalline semiconductor area, different layers of semiconductor materials, such as germanium and other materials, may be provided in combination with silicon layers or portions, wherein such a configuration may still be considered as a silicon-based material.

In this respect, the substrate 201 may represent, in one illustrative embodiment, a silicon-based crystalline semiconductor substrate above which is provided a substantially crystalline silicon-based semiconductor layer 203. In still other illustrative embodiments, the substrate 201 may represent any appropriate carrier material having formed thereon an insulating layer 202, such as a silicon dioxide layer, a silicon nitride layer and the like, above which is formed the crystalline semiconductor layer 203, which may be provided, in one illustrative embodiment, as a silicon-based layer. The semiconductor layer 203 may have an appropriate thickness for forming therein corresponding drain and source regions in accordance with design requirements. For example, the semiconductor layer 203 may have a thickness that is appropriate to form therein partially or fully depleted transistor elements when SOI-like transistor architectures are considered, while, in other embodiments, the semiconductor layer 203 may represent an epitaxially grown upper portion of a bulk semiconductor substrate.

In this manufacturing stage, the semiconductor device 200 may further comprise a gate electrode 204 which may be comprised of any appropriate material, such as polysilicon, and the like, which is separated from the semiconductor layer 203 by a gate insulation layer 205. Moreover, a liner 206 may be provided to cover exposed portions of the semiconductor layer 203 as well as the gate electrode 204. For instance, the liner 206 may be comprised of silicon dioxide, silicon nitride, silicon oxynitride or any other appropriate material, wherein a thickness of the liner 206 may be selected such that a desired masking effect may be obtained for a doped region 207, which may represent an extension region for respective drain and source regions still to be formed. For example, the doped region 207 may represent a P-doped region or an N-doped region, depending on the conductivity type of the field effect transistors to be formed. Moreover, substantially amorphized regions 212 may be formed adjacent to the gate electrode 204 within the semiconductor layer 203, wherein the substantially amorphized regions 212 extend below the gate electrode corresponding to a distance 212D that may represent, in some illustrative embodiments, a distance of approximately 10-30% of the length of the gate electrode 204, indicated by 204L. In other illustrative embodiments (not shown), the substantially amorphized region 212 may extend up to approximately 50% or even more below the gate electrode 204, so that the regions 212 may merge below the gate electrode 204 to form a substantially continuous region.

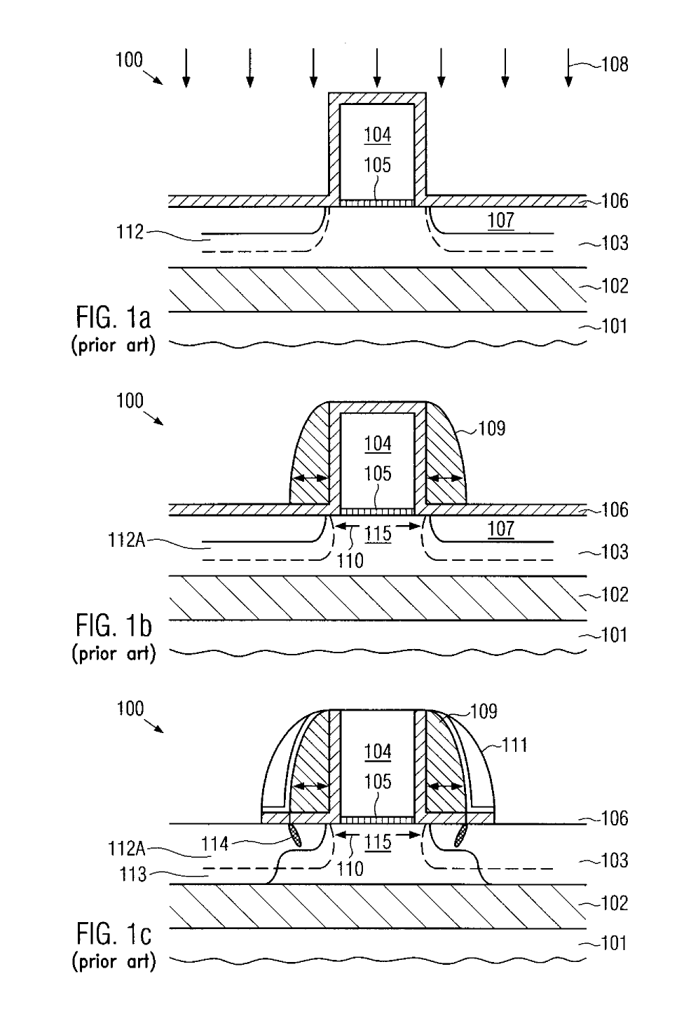

A typical process flow for forming the semiconductor device 200 as shown in FIG. 2a may comprise the following processes. After forming the semiconductor layer 203 by epitaxial growth techniques or by providing a respective SOI-like substrate, any appropriate well-established implantation and other manufacturing processes may be performed for forming a desired vertical dopant profile and corresponding isolation structures, as previously explained with reference to FIG. 1a. Thereafter, the gate insulation layer 205 and the gate electrode 204 may be formed on the basis of well-established processes as are also previously described. Subsequently, the liner 206 may be formed on the basis of well-established recipes. Thereafter, in one illustrative embodiment, the doped region 207 may be formed by a corresponding implantation process. For example, a heavy dopant, such as arsenic, may be introduced on the basis of well-established techniques using appropriate implantation dose and energy parameters for obtaining a desired dopant concentration and implantation depth for the region 207. In this case, the implantation is substantially self-amorphizing, thereby providing a substantially preamorphized surface region for the regions 212 still to be formed on the basis of a subsequent implantation process 208. In other embodiments, when a moderately light ion species is to be implanted for forming the doped region 207, an amorphization implantation 208 may be performed first, wherein the implantation 208 comprises at least one implantation phase, in which the implantation species is provided with a tilt angle, indicated as α and −α for producing the desired horizontal amorphization profile such that the regions 212 extend below the gate electrode 204. For instance, in some illustrative embodiments, the tilt angle α may be selected within a range of approximately 10-50 degrees. It should be appreciated that a direction substantially perpendicular to the semiconductor layer 203 represents the 0 degrees direction. During the implantation 208, the values for the tilt angles α and −α may be selected differently, when a non-symmetric design of the regions 212 may be considered advantageous.

In some illustrative embodiments, the implantation 208 may comprise at least one further implantation step, in which a substantially non-tilted implantation is performed, wherein an energy is selected such that a portion of the semiconductor layer 203 in the vicinity of the surface thereof is substantially amorphized. For example, germanium, xenon, krypton, silicon or other more or less heavy ion species may be appropriate for efficiently destroying the crystalline structure of the layer 203 within the regions 212. Thus, in the preceding embodiment comprising at least one substantially non-tilted implantation phase, a moderately low energy, in the range of 1-5 kV for germanium may be selected so as to substantially amorphize the surface portion of the layer 203, wherein a corresponding implantation dose is less critical as long as the threshold for amorphization is exceeded. For example, an implantation dose of 1×10¹⁵ ions/cm² may be appropriate. Thereafter, one or more tilted implantation steps may be performed with increased energy in order to position the respective implantation species at an appropriate depth for obtaining the required vertical and horizontal amorphization profile.

In still other embodiments, the implantation process 208 may be performed as a single process or as a sequence of tilted implantations, wherein the implantation energy may be varied in order to obtain a substantially amorphized state in substantially each depth of the respective regions 212. For example, using a tilt angle of 30-50 degrees, a first reduced implantation energy may be selected for amorphizing near-surface areas of the region 212 and a second increased implantation energy may be selected to amorphize deeper lying portions of the regions 212. It should be appreciated, however, that other implantation regimes may be used, as long as an increased extension of the regions 212 below the gate electrode 204 is achieved.

As previously explained, for light dopant species, such as boron, it may be advantageous to perform the amorphization implantation 208 prior to the implantation for forming the region 207, thereby significantly reducing any channeling effects that may typically be encountered during the implantation of light dopant species.

After the formation of the regions 212 and 207, a spacer layer (not shown) may be formed by appropriate deposition techniques, such as PECVD, during which the deposition parameters are controlled such that a desired high intrinsic stress is generated in the respective spacer layer. As is well known, stress in a plurality of layers may be controlled on the basis of the respective deposition parameters, such as temperature, pressure, ion bombardment during deposition and the like. For example, silicon nitride is a material that is well known in the art and that may be deposited on the basis of appropriately selected deposition parameters to create tensile or compressive stress up to a magnitude of approximately 1.5 GigaPascal (GPa) or even more. In one illustrative embodiment, after the formation of the respective spacer layer, a heat treatment may be performed to substantially re-crystallize the regions 212, which may be accomplished on the basis of any appropriate anneal techniques, such as laser-based anneal techniques or other oven-based methods. In other illustrative embodiments, the highly-stressed spacer layer may be patterned by performing an anisotropic etch process on the basis of well-established recipes in order to form respective spacer elements at sidewalls of the gate electrode 204. Thereafter, an appropriate heat treatment may be performed in order to re-crystallize the regions 212.

FIG. 2b schematically shows the semiconductor device 200 after the completion of the above-described process sequence. Hence, the device 200 comprises respective spacer elements 209 which may have a specific intrinsic stress, such as compressive or tensile stress. For example, it may be assumed that the spacers 209 have high tensile stress when the semiconductor device 200 is to represent an N-channel transistor. Moreover, due to the preceding heat treatment, the regions 212 are now substantially re-crystallized in a strained state, wherein, in some illustrative embodiments, a respective substantially continuous strained crystalline region may even be formed below the entire gate electrode 204, wherein, depending on the amorphization species used during the implantation 208, a corresponding enhanced concentration of these species may be present in the respective strained crystalline region, which is now indicated as 212A. It should be appreciated that, even in the case where the substantially amorphized regions 212 do not merge, as is shown in FIG. 2a, a corresponding diffusion activity during an initial phase of the heat treatment for re-crystallizing may drive the corresponding species more deeply below the gate electrode 204 so that the corresponding re-crystallization process may also take place in a region 212C, which may have not been amorphized during the preceding implantation process 208. Consequently, the creation of crystalline defects during the strained re-crystallization may be significantly reduced as the re-crystallization process may take place in the substantially continuous region 212A. It should be appreciated that even an increased defect rate in the area 212C may not contribute to leakage currents as heavily as in the conventional device shown in FIG. 1c, since, in this case, the respective crystalline defects may be located farther away from respective PN junctions still to be formed in the device 200.

Thereafter, further processing may be continued on the basis of well-established techniques, for instance, by forming respective drain and source regions by ion implantation, possibly requiring the formation of further spacer elements. In other illustrative embodiments, the heat treatment may not be performed at this stage and, instead, the manufacturing process may be continued with a further implantation process for forming drain and source regions.

FIG. 2c schematically shows the semiconductor device 200 in accordance with such an embodiment, in which an implantation process 220 is performed for forming drain and source regions 213. For this purpose, appropriate implantation parameters may be selected to introduce the desired dopant species into the semiconductor layer 203, wherein the substantially amorphized regions 212 provide reduced channeling effects, especially when a light dopant species, such as boron, is to be implanted. Furthermore, the device 200 may be subjected to an appropriate heat treatment for re-crystallizing the regions 212 and for activating the dopants in the regions 207 and 213. Similarly, as explained above, the corresponding re-crystallization process may result in a significantly reduced number of crystalline defects and/or with a relocation of the respective crystalline defects away from the respective PN junctions.

FIG. 2d schematically shows the semiconductor device 200 in accordance with yet other illustrative embodiments, in which a more complex lateral dopant profile is required. For this purpose, a further spacer 211 is formed adjacent to the spacer 209, possibly on the basis of a further liner 221. In some illustrative embodiments, the regions 212 may still be present in their substantially amorphous states and the spacer 211 may be provided to also exhibit a high intrinsic stress of the same type as the spacer 209. Moreover, the device 200 may be exposed to a further implantation process 222 for refining the lateral dopant profile, thereby forming the drain and source regions 213A in accordance with device requirements. It should be appreciated that even further spacer elements may be provided to further enhance or refine the corresponding lateral dopant profile in the drain and source regions 213A.

FIG. 2e schematically shows the semiconductor device 200 during a heat treatment 223 for re-crystallizing the regions 212 and for activating the dopants previously implanted in order to provide the drain and source regions 213A in their final state. As previously explained, in some illustrative embodiments, the re-crystallization process may result in a substantially continuous region extending below the entire gate electrode 204, thereby significantly reducing the creation of crystalline defects, such as zipper defects and the like. Moreover, during the re-crystallization process, the highly stressed spacer elements 209 and 211 provide a strained semiconductor material in the previously amorphized regions 212, thereby also providing a desired strain 210 below the gate electrode 204. Consequently, a highly efficient strain-generating mechanism is provided, wherein, depending on the type of transistor, the spacers 209 and/or 211, or respective spacer layers for forming the same, may be provided to generate the strain 210 as a compressive or tensile strain. Moreover, it should be appreciated that the strain-generating mechanism as provided by the present invention may be highly efficiently combined with other strain-inducing mechanisms, such as the provision of contact layers to be formed on or above the device 200 after the formation of any metal silicide regions therein. Moreover, as previously explained, embedded crystalline strain layers of compound semiconductors may be provided, for instance, on the basis of silicon/germanium, silicon/carbon and the like, wherein well-established techniques for recessing the semiconductor layer 203 adjacent to the gate electrode 204 may be used, followed by appropriate selective epitaxial growth techniques. In this case, the process sequence described above with reference to FIGS. 2a-2e may be performed after the completion of the epitaxial growth process, wherein, in some embodiments, one type of transistor may receive a corresponding epitaxially grown semiconductor material, while the other transistor type may not be provided with a strain-inducing semiconductor layer. For instance, silicon/germanium may be selectively grown in P-channel transistors, while the above-described process sequence may be efficiently applied to N-channel transistors, wherein the provision of sidewall spacers of high tensile stress may be efficiently over-compensated for at the P-channel transistor side by the respective embedded silicon/germanium layer. Moreover, it should be appreciated that the above-described tilted implantation 208 may be performed separately for different transistor types so as to appropriately select implantation parameters with respect to other device requirements.

FIG. 2f schematically shows the semiconductor device 200 in accordance with further illustrative embodiments, in which the tilted implantation 208 is performed at a later manufacturing phase, when implantation-induced damage in the vicinity of the gate insulation layer 205 and at sidewalls of the gate electrode 204 that may be caused by the tilted amorphization implantation 208 are considered inappropriate. Hence, the semiconductor device 200 may comprise the spacer elements 209 with a high intrinsic stress, wherein the spacers 209 now efficiently protect a lower portion of the gate electrode 204 and the adjacent gate insulation layer 205 from undue implantation damage. Regarding the specifics of the implantation 208, the same criteria apply as previously explained with reference to FIG. 2a. It should be appreciated that the doped region 207 may be formed prior to the formation of the spacer elements 209, while, in other illustrative embodiments, the region 207 may also be formed on the basis of a tilted implantation, wherein the respective implantation for introducing the dopants into the region 207 may be performed prior to or after the amorphization implantation 208, as is also previously discussed with reference to FIG. 2a. In some embodiments, prior to the formation of the spacer elements 209, an essentially non-tilted implantation step may be performed so as to also efficiently amorphize a region immediately below the spacers 209. Thereafter, the spacers 209 may be formed and the tilted implantation 208 may be performed with moderately high tilt angles in the above-specified range to form the respective amorphized regions 212 to extend below the gate electrode 204. Next, a further implantation may be performed, for instance for forming the drain and source regions, wherein a respective implantation thereof may require the formation of one or more further spacer elements, as is also previously explained.

FIG. 2g schematically shows the semiconductor device 200 in a further advanced manufacturing stage, wherein the at least one further spacer element 211 is formed adjacent to the spacer element 209. The spacers 211 may also exhibit the high intrinsic stress of the same type as the spacer element 209 in order to promote a strained re-crystallization of the regions 212 in a heat treatment, such as the treatment 223 described with reference to FIG. 2e. Consequently, the device 200 as shown in FIG. 2g comprises the desired type of strain 210 below the gate electrode 204, wherein, due to the amorphized regions 212 extending below the gate electrode 204, a significantly reduced number of defects during the re-crystallization process may be obtained or the creation of zipper defects in sensitive transistor areas may be avoided or at least significantly reduced. Moreover, due to the provision of the spacer element 209 prior to the tilted implantation 208, in sophisticated applications, undue implantation-induced damage on sidewalls of the gate electrode 204 and the gate insulation layer 205 may be avoided or at least substantially reduced. Hence, a significant performance gain may be achieved, wherein an undue increase of leakage currents may be avoided or at least significantly reduced.

With reference to FIGS. 3a-3e, further illustrative embodiments of the present invention will now be described in more detail, in which the strain-generating mechanism, as is described previously with reference to FIGS. 2a-2e, may be applied to different transistor types, wherein each transistor type may receive a specified type of strain.

In FIG. 3a, a semiconductor device 350 comprises a first transistor 300P and a second transistor 300N, which are formed above a substrate 301 having formed thereon, in some illustrative embodiments, a buried insulating layer 302 and a semiconductor layer 303. Regarding the substrate 301, the buried insulating layer 302 and the semiconductor layer 303, the same criteria apply as is previously explained in context with the components 201, 202 and 203. The first and second transistors 300P, 300N may each comprise a gate electrode 304 formed on respective gate insulation layers 305. Furthermore, respective first spacers 309 are formed at sidewalls of the respective gate electrodes 304, wherein a corresponding liner 306 may be provided. The first spacers 309 may have a specified intrinsic stress, such as tensile or compressive stress. Moreover, respective doped regions 307 may be formed in each of the transistors 300N, 300P, and respective amorphized regions 312 may be formed adjacent to the gate electrodes 304 and extending below the gate electrodes 304 as is also explained with reference to FIG. 2f. The transistors 300N, 300P may be formed on the basis of the same process recipes and strategies as are previously described with reference to the device 200. Furthermore, in some illustrative embodiments, respective tilted implantations 308N, 308P may have been performed prior to the formation of the first spacer 309, wherein the implantations 308N, 308P may have been performed commonly for both transistors or may have been performed separately by respectively covering one of the transistors while performing the tilted implantation 308 in the other transistor, and vice versa. In one illustrative embodiment, as shown in FIG. 3a, the tilted implantation 308N and 308P are performed on the basis of the first spacer 309, thereby significantly reducing any implantation-induced damage in the gate electrodes 304 and the respective gate insulation layers 305. Moreover, again, the implantation 308N, 308P may be provided as a common process or may be performed separately for each of the transistors 300N, 300P. It should also be appreciated that regarding the specifics of the implantation processes 308N, 308P on the basis of the spacers 309, the same criteria apply as previously explained with reference to FIG. 2f.

FIG. 3b schematically illustrates the semiconductor device 350 in a further advanced manufacturing stage, in which a further spacer 311 may be formed adjacent to the spacer 309, which may be commonly referred to as first spacer elements. Moreover, respective drain and source regions 313A are formed in the first and second transistors 300P, 300N. Moreover, first transistor 300P may be covered by a resist mask 330, which exposes the second transistor 300N. Moreover, the semiconductor device 350 may be exposed to an etch sequence 331 for removing the first spacers 311, 309 from the second transistor 300N. For example, highly selective etch recipes for silicon nitride and silicon dioxide are well established in the art and may be used for selectively removing the first spacers 311, 309.

FIG. 3c schematically shows the semiconductor device 350 after the completion of the etch sequence 331 and after the removal of the resist mask 330. Moreover, in one illustrative embodiment, the etch sequence 331 may also comprise the removal of the liner 306 of the second transistor 300N. Consequently, the gate electrode 304 of the second transistor 300N may be exposed, while the first spacers 311, 309 are still provided in the first transistor 300P.

FIG. 3d schematically shows the semiconductor device 350 in a further advanced manufacturing stage. An etch stop layer 318 is conformally formed on the device 350 and thereon is provided a spacer layer 319 which may exhibit a second type of stress that differs from the type of stress of the first spacers 309 and 311. For example, the spacer layer 319 may represent a silicon nitride layer having a high tensile stress, when the second transistor 300N is to represent an N-channel transistor. Consequently, the first spacers 309 and 311 may comprise a high compressive stress, which may be advantageous in generating a corresponding strain when the first transistor 300P represents a P-channel transistor. Moreover, the device 350 may be exposed to an anisotropic etch ambient 324 for patterning the spacer layer 319 to thereby form a respective second spacer element 319S as is indicated by the dashed line. During the anisotropic etch process 324, corresponding sidewall spacers may also be formed adjacent to the first spacers 309 and 311, which may then be selectively removed by providing a corresponding resist mask for covering the second transistor 300N, while exposing the first transistor 300P. During a subsequent selective etch process, the residues of the spacer layer 319 formed on the first transistor 300P may be removed using the etch stop layer 318 for efficiently controlling the etch process without substantially affecting the first spacers 309, 311.

FIG. 3e schematically shows the semiconductor device 350 after the completion of the above-described process sequences. Hence, the device 350 comprises the second spacer 319S having the second type of stress, while the first spacers 309, 311 having the first type of stress are formed in the first transistor 300P. Moreover, the device 350 is subjected to a heat treatment 323 for re-crystallizing the substantially amorphized regions 312 and for activating the dopants within the drain and source regions 313A. As previously explained, due to the initial shape of the amorphized regions 312, which significantly extend below the respective gate electrodes 304, wherein different shapes and profiles may be created when the respective implantations 308N, 308P are performed as separate implantation processes, a substantially homogeneous and continuous re-crystallization process may be achieved, thereby avoiding or at least significantly reducing the number of crystalline defects and/or positioning such defects within less critical device regions, i.e., more distant from respective PN junctions of the first and second transistors 300P, 300N. Due to the re-crystallization on the basis of the respectively stressed first and second spacers 309, 311 and 319S, a corresponding strain 31ON in the second transistor 300N and 310P in the first transistor 300P may be achieved, wherein a high degree of flexibility in adjusting the type and magnitude of the respective strain is provided. Consequently, an efficient stress engineering for separately adjusting the characteristics of N-channel transistors and P-channel transistors may be accomplished, wherein, as previously explained, the device 350 may receive or may comprise additional stress sources, such as embedded strain-inducing crystalline layers and the like.

As a result, the present invention provides an improved technique for the creation of a desired strain in channel regions of transistors by re-crystallizing substantially amorphized regions in the presence of respectively stressed overlying spacers or spacer layers, wherein a defect rate during the re-crystallization may be significantly reduced and/or the locations of respective crystalline defects may be shifted to less critical device regions, by appropriately modifying the horizontal shape and location of the amorphized regions. For this purpose, a tilted amorphization implantation may be used so as to drive the resulting substantially amorphized region significantly below the respective gate electrode, wherein the subsequent re-crystallization process on the basis of a stressed spacer or spacer layer may result in a substantially continuous re-grown crystalline region below the gate electrode. Moreover, the corresponding strain-creating mechanism may be separately applied to different types of transistors, thereby providing enhanced flexibility in separately adapting the characteristics of PMOS and NMOS transistors.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a substantially amorphized region in an initially crystalline semiconductor layer adjacent to and extending below a gate electrode formed above said semiconductor layer by a tilted implantation process;
forming a stressed layer having a specified intrinsic stress at least above a portion of said semiconductor layer so as to transfer stress into said semiconductor layer; and
re-crystallizing said substantially amorphized region in the presence of said stressed layer by performing a heat treatment.

2. The method of claim 1, wherein forming said stressed layer comprises conformally depositing a spacer layer with said specified stress and anisotropically etching said spacer layer to form a first spacer at a sidewall of said gate electrode as said stressed layer.

3. The method of claim 1, wherein said specified intrinsic stress has a magnitude of approximately 1 GPa (GigaPascal) or higher.

4. The method of claim 3, wherein said specified intrinsic stress is a tensile stress and said gate electrode represents the gate electrode of an N-channel transistor.

5. The method of claim 3, wherein said specified intrinsic stress is a compressive stress and said gate electrode represents the gate electrode of a P-channel transistor.

6. The method of claim 1, further comprising implanting a dopant species into said substantially amorphized region to form drain and source regions in said semiconductor layer.

7. The method of claim 6, wherein said heat treatment is performed after said dopant species is implanted.

8. The method of claim 6, wherein said heat treatment is performed prior to implanting said dopant species.

9. The method of claim 2, further comprising forming a second spacer adjacent to said first spacer prior to performing said heat treatment, wherein said second spacer has said specified intrinsic stress.

10. The method of claim 9, further comprising implanting a dopant species into said semiconductor layer after forming at least one of said first spacer and said second spacer.

11. The method of claim 10, wherein said heat treatment is performed after implanting said dopant species.

12. The method of claim 2, wherein said tilted implantation process is performed after forming said first spacer.

13. The method of claim 12, further comprising forming a second spacer adjacent to said first spacer prior to performing said heat treatment, said second spacer having said specified intrinsic stress.

14. The method of claim 13, further comprising implanting a dopant species into said semiconductor layer using at least one of said first and second spacers as an implantation mask.

15. The method of claim 14, wherein said heat treatment is performed after implanting said dopant species.

16. A method, comprising:
forming a first substantially amorphized region adjacent to and extending below a first gate electrode formed above an initially substantially crystalline semiconductor layer;
forming a second substantially amorphized region adjacent to and extending below a second gate electrode formed above said semiconductor layer;
forming a first spacer at a sidewall of said first gate electrode, said first spacer having a first type of stress;
forming a second spacer at a sidewall of said second gate electrode, said second spacer having a second type of stress other than said first type; and
re-crystallizing said first and second substantially amorphized regions in the presence of said first and second stressed spacers by performing a heat treatment.

17. The method of claim 16, wherein forming said first and second substantially amorphized regions comprises performing a tilted implantation process.

18. The method of claim 17, wherein said tilted implantation process comprises a first implantation process for forming the first substantially amorphized region and a second implantation process for forming the second substantially amorphized region.

19. The method of claim 18, wherein said first and second substantially amorphized regions are formed in a common tilted implantation sequence.

20. The method of claim 16, wherein said first and second substantially amorphized regions are formed after forming said first and second spacer.

21. The method of claim 16, wherein forming said first and second spacers comprises commonly forming said first spacer at said first and second gate electrodes, selectively removing said first spacer from said second gate electrode, forming a spacer layer having said second type of stress above said first and second gate electrodes, forming said second spacer from said spacer layer and selectively removing residues from said spacer layer from said first gate electrode.
